(19) United States
(12) Patent Application Publication
(10) Pub. No.: US 2016/0381793 A1
(43) Pub. Date: Dec. 29, 2016

(54) WIRING BOARD AND METHOD FOR MANUFACTURING THE SAME

(71) Applicant: KYOCERA Corporation, Kyoto-shi (JP)

(72) Inventors: Masaharu YASUDA, Kobe-shi (JP); Yoshihiro HASEGAWA, Yasu-shi (JP)

(73) Assignee: KYOCERA Corporation, Kyoto-shi (JP)

(21) Appl. No.: 15/189,255

(22) Filed: Jun. 22, 2016

(30) Foreign Application Priority Data
Jun. 24, 2015 (JP) 2015-126539
Jul. 27, 2015 (JP) 2015-147375

(51) Int. Cl. H05K 1/02; H05K 3/46; H05K 1/11; H05K 3/10

(52) U.S. Cl. CPC H05K 1/0298; H05K 3/107; H05K 3/4644; H05K 1/115; H05K 2201/09209

(57) ABSTRACT

A wiring board of the present disclosure includes an insulating layer and a wiring conductor. The wiring conductor is buried in an insulating layer in such a manner as to have a top surface exposed to a surface of the insulating layer. The wiring conductor includes, at a portion buried in the insulating layer, a wiring level difference part or a wiring inclined part having a width larger than a width of the top surface.

### BACKGROUND OF THE INVENTION

1. Technical Field

The present invention relates to a wiring board having high-density micro wiring, and a method for manufacturing the wiring board.

2. Background

Conventionally, a wiring board including a plurality of insulating layers has wiring conductors between the insulating layers or on the surface of the outermost insulating layer. A plurality of via holes are formed in each insulating layer. Inside each via hole, a via conductor integrally formed with the wiring conductor is deposited. The via conductor enables a conduction between the wiring conductors formed on each insulating layer. A wiring conductor in the highest layer is buried in the insulating layer in such a manner as to have the top surface exposed to the surface of the insulating layer. Further, a part of each wiring conductor in the highest layer forms a semiconductor element connection pad. To the semiconductor element connection pad, an electrode of a semiconductor element such as a semiconductor integrated circuit element is connected via a solder. A part of each wiring conductor formed in the lowest layer forms a circuit board connection pad. To the circuit board connection pad, an electrode of the circuit board on which the wiring board is mounted is connected. Then, an electrical signal is transmitted between the semiconductor element and the circuit board via the wiring conductor, so that the semiconductor element is operated. Such a wiring board is described in Japanese Unexamined Patent Publication No. S63-232483, for example.

### SUMMARY

A wiring board of the present disclosure includes an insulating layer and a wiring conductor, wherein the wiring conductor is buried in the insulating layer in such a manner as to have a top surface exposed to a surface of the insulating layer, and wherein the wiring conductor includes, at a portion buried in the insulating layer, a wiring level difference part or a wiring inclined part having a width larger than a width of the top surface.

A method for manufacturing a wiring board of the present disclosure includes the following processes. On an underlying metal layer, there is formed a resist layer for plating which has an opening pattern including an opening level difference part or an opening inclined part having a width being smaller toward the underlying metal layer. In the opening pattern, there is filled with a plated metal layer for a wiring conductor having a wiring level difference part or a wiring inclined part corresponding to the opening level difference part or the opening inclined part, and the resist layer for plating is removed. An insulating layer burying entirely the plated metal layer is formed on the underlying metal layer and on the plated metal layer, and the underlying metal layer is removed by etching. Finally, there is formed a wiring conductor having a top surface exposed from the insulating layer and including, at a portion buried in the insulating layer, the wiring level difference part or the wiring inclined part having a width larger than a width of the top surface.

### BRIEF DESCRIPTION OF THE DRAWINGS

FIG. 1 is a schematic cross-sectional view showing an embodiment of a wiring board according to the present disclosure;

FIG. 2 is a main-part enlarged cross-sectional view showing the embodiment of the wiring board according to the present disclosure;

FIGS. 3A to 3D are schematic cross-sectional views for explaining an embodiment of a method for manufacturing a wiring board according to the present disclosure;

FIGS. 4E to 4I are schematic cross-sectional views for explaining the embodiment of the method for manufacturing a wiring board according to the present disclosure;

FIGS. 5J to 5L are schematic cross-sectional views for explaining the embodiment of the method for manufacturing a wiring board according to the present disclosure;

FIGS. 6M to 6O are schematic cross-sectional views for explaining the embodiment of the method for manufacturing a wiring board according to the present disclosure;

FIG. 7 is a main-part enlarged cross-sectional view showing another embodiment of a wiring board according to the present disclosure;

FIG. 8 is a main-part enlarged cross-sectional view for explaining another embodiment of a method for manufacturing a wiring board according to the present disclosure; and

FIG. 9 is a main-part enlarged cross-sectional view for explaining still another embodiment of a method for manufacturing a wiring board according to the present disclosure.

### DETAILED DESCRIPTION

Along the progress of miniaturization of a wiring conductor, a contact area between a wiring conductor and an insulating layer becomes smaller. As a result, the adhesion strength of the wiring conductor becomes smaller, and the wiring conductor becomes easily peeled off from the insulating layer. Therefore, the electrical signal cannot be satisfactorily transmitted via the wiring conductor, and thus a semiconductor element does not stably operate in some cases.

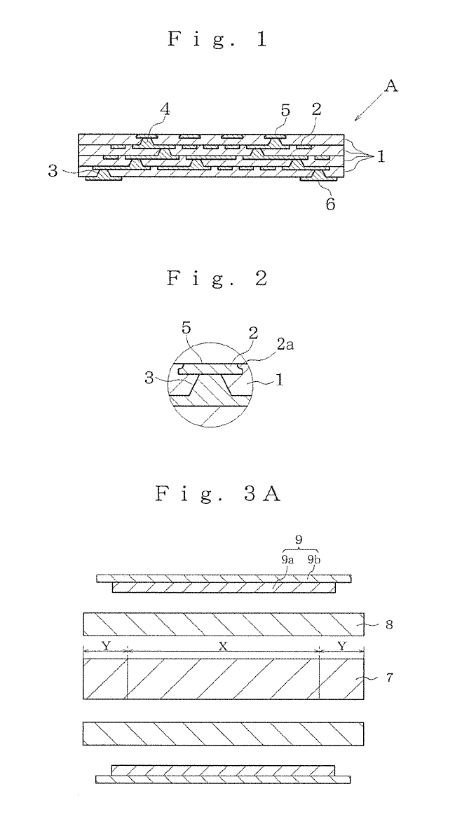

In the wiring board of the present disclosure, a wiring conductor buried in an insulating layer in such a manner as to have a top surface exposed to a surface of the insulating layer includes, at a portion buried in the insulating layer, a wiring level difference part or a wiring inclined part having a width larger than a width of the top surface. As described above, because the wiring level difference part or the wiring inclined part having a width larger than a width of the top surface is buried in the insulating layer, peeling off of the wiring conductor from the insulating layer can be suppressed. Hereinafter, a wiring board according to one embodiment of the present disclosure will be described with reference to FIG. 1 and FIG. 2. FIG. 2 is a main-part enlarged view of FIG. 1.

As shown in FIG. 1, a wiring board A of the one embodiment has a multilayer structure having insulating layers 1 laminated in four layers, for example, and has wiring conductors 2 formed between the insulating layers 1 and on the surface of the outermost insulating layer 1. Each insulating layer 1 is formed of a thermosetting resin such as an epoxy resin or a bismaleimide triazine resin, and an inorganic insulating filler may be dispersed in the thermosetting resin. In the insulating layer 1, a plurality of via holes 3 in which a via conductor 4 is filled to enable a conduction between the insulating layers 1 are formed, by laser processing, for example. Each via hole 3 may have a diameter of about 20 μm to 100 μm, for example. Inside the via hole 3, a via conductor 4 integrally formed with the wiring conductor 2 is deposited.

The wiring conductor 2 is formed of a satisfactory conductive material such as a non-electrolytic plating or an electrolytic plating. A part of the wiring conductor 2 in the highest layer forms a semiconductor element connection pad 5. To the semiconductor element connection pad 5, there is connected an electrode of a semiconductor element such as a semiconductor integrated circuit element. A part of each wiring conductor 2 formed in the lowest layer forms a circuit board connection pad 6. To the circuit board connection pad 6, there is connected an electrode of the circuit board on which the wiring board A is mounted. Then, an electrical signal is transmitted between the semiconductor element and the circuit board via the wiring conductor 2, so that the semiconductor element is operated. As shown in FIG. 2, the wiring conductor 2 in the highest layer is buried in the insulating layer 1 in such a manner as to have the top surface exposed to the surface of the insulating layer 1. Further, the wiring conductor 2 in the highest layer includes, at a portion buried in the insulating layer 1, a wiring inclined part 2a having a width larger than a width of the top surface.

As described above, according to the wiring board of the present disclosure, the wiring inclined part 2a having a width larger than a width of the top surface is buried in the insulating layer 1. Therefore, even when miniaturization of the wiring conductor 2 is progressed, the adhesion strength of the wiring conductor 2 does not easily become small, and peeling off of the wiring conductor 2 from the insulating layer 1 can be prevented. As a result, because the electrical signal can be transmitted satisfactorily via the wiring conductor 2, a wiring board enables a stable operation of the semiconductor element.

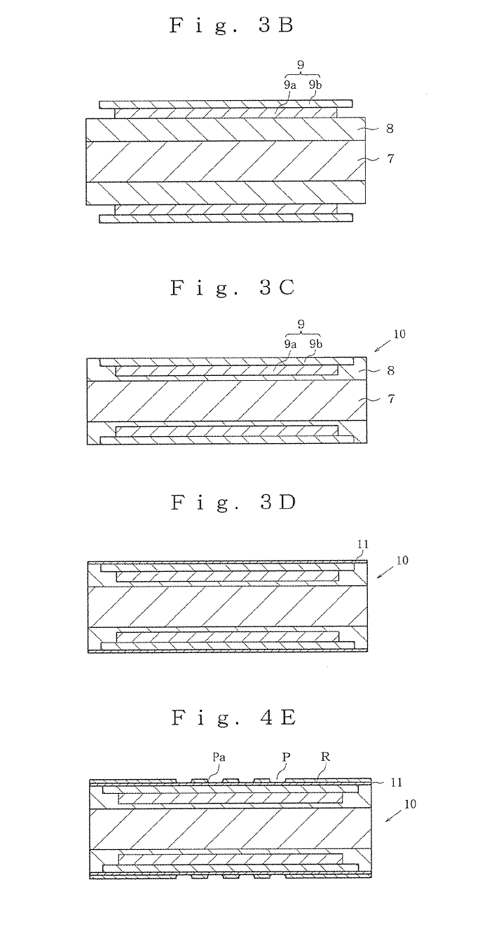

Next, a method for manufacturing a wiring board according to an embodiment of the present disclosure will be described with reference to FIGS. 3A to 3D to FIGS. 6M to 6O. The same portions as FIG. 1 are denoted by the same reference characters, and detailed description thereof will be omitted.

As shown in FIG. 3A, there are prepared a prepreg 7, two adhesive films 8, and two separable metal foils 9. The prepreg 7 is used to form a supporting substrate 10 for supporting, by maintaining a necessary flatness, the wiring board A in the middle of manufacturing when manufacturing the wiring board A. The prepreg 7 has a product-forming region X at the center, and a margin region Y at an outer periphery.

The product-forming region X is a region of a quadrangular shape, and the wiring board A is formed on the product-forming region X. In the one embodiment, for simplicity, only the product-forming region X corresponding to one wiring board A is shown. Actually, the product-forming region has an area corresponding to dozens to several thousand wiring boards A. The margin region Y is in a quadrangular frame shape surrounding the product-forming region X. The prepreg 7 has approximately a quadrangular shape, and may have a thickness of about 0.1 mm to 0.2 mm, and may have longitudinal and lateral lengths of 400 mm to 900 mm each. The prepreg 7 has a plate shape in a semi-cured state by having a glass fiber impregnated with a thermosetting resin such as an epoxy resin.

The adhesive film 8 is interposed between the prepreg 7 and the separable metal foil 9, and causes the cured prepreg 7 and the separable metal foil 9 to be deposited together. The adhesive film 8 may have a thickness of about 24 μm to 50 μm, and may have longitudinal and lateral lengths of 400 mm to 900 mm each. The adhesive film 8 is formed of a heat-resistant film such as an epoxy resin or a polyimide resin.

The separable metal foil 9 includes a first metal foil 9a and a second metal foil 9b. The first metal foil 9a and the second metal foil 9b are separably held by a small adhesive force, via an adhesion layer (not shown). The first metal foil 9a has a size larger than the product-forming region X and smaller than the second metal foil 9b. The first metal foil 9a may have a thickness of about 15 μm to 20 μm. The second metal foil 9b has longitudinal and lateral sizes smaller by about 5 mm than longitudinal and lateral sizes of the prepreg 7. The first metal foil 9a may have a thickness of about 5 μm to 9 μm.

The separable metal foil 9 includes copper, for example. The adhesion layer may be formed of a heat-resistant pressure-sensitive adhesive such as a silicon resin system or an acrylic resin system, or of a metal layer of a nickel system, that can bear heat load applied during the forming of the wiring board A. Such an adhesion layer may have a small pressure-sensitive adhesive force of about 1 N/m to 9 N/m, in separating the first metal foil 9a and the second metal foil 9b without leaving a peel-off remain, at the time of separating a build-up portion 12 described later from the supporting substrate 10.

Next, as shown in FIG. 3B, on the center parts on the upper and lower surfaces of the prepreg 7, the separable metal foils 9 are disposed via the adhesive film 8 so as to have the first metal foil 9a positioned on the prepreg 7 side. The laminated body shown in FIG. 3B is heated while pressing the laminated body from above and below. By pressing and heating in this way, the supporting substrate 10 having the separable metal foils 9 fixed to the upper and lower surfaces of the cured prepreg 7 is formed, as shown in FIG. 3C. Next, as shown in FIG. 3D, conductor layers 11 (underlying metal layers) are formed on both main surfaces of the supporting substrate 10 including the separable metal foils 9. Each conductor layer 11 is formed by a known plating method, for example, and may have a thickness of about 0.01 μm to 0.1 μm.

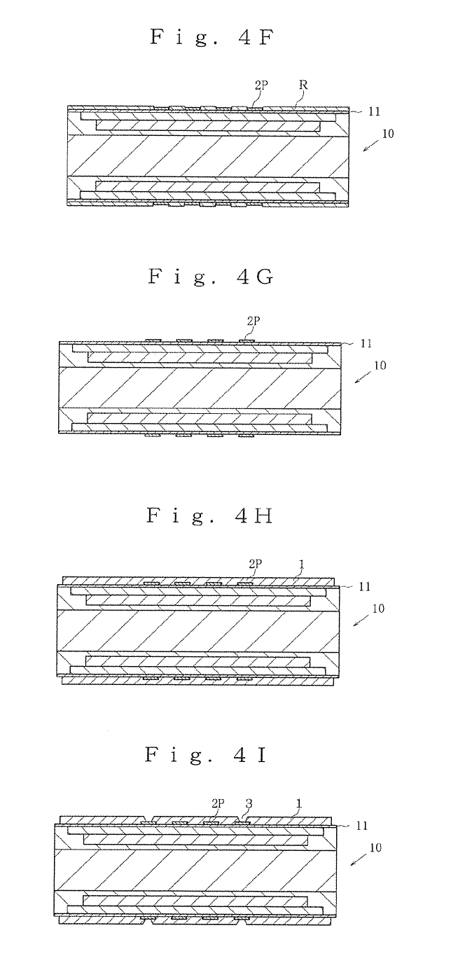

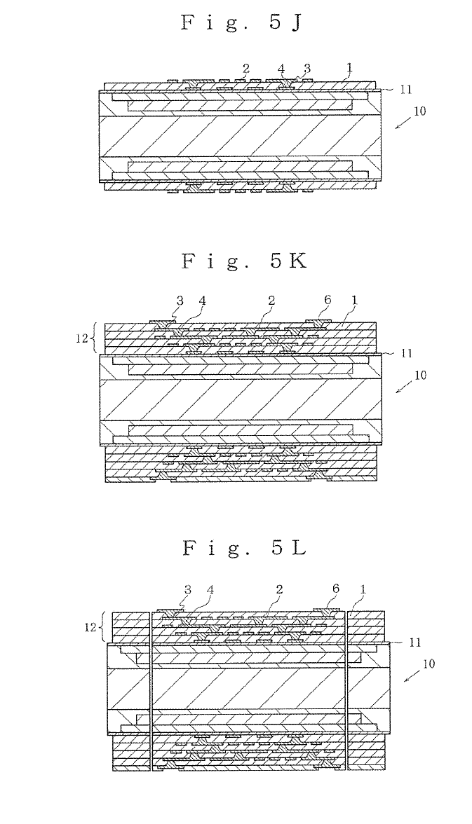

As shown in FIG. 4E, on the surfaces of the conductor layers 11, there are deposited resists R for plating each having a plurality of opening patterns P corresponding to the wiring pattern. The opening pattern P includes an opening inclined part Pa having a width being smaller toward the conductor layer 11 side. The resist R for plating is formed as follows, for example. First, a resin sheet or a resin paste formed of a photosensitive resin is deposited or coated to the surface of the conductor layer 11. The photosensitive resin is exposed to light via a light-shielding mask applied to a portion corresponding to the opening pattern P. Next, the photosensitive resin is developed and the unexposed portion is removed, so that the resist R for plating having the opening pattern P is formed.

For example, the opening inclined part Pa is formed by flattening the surface of the conductor layer 11. The conductor layer 11 may have a surface roughness (Ra) equal to or smaller than 60 nm. Based on the flattening of the surface of the conductor layer 11, incident light at the time of exposure which reaches the surface of the conductor layer 11 is not blocked by a convex part of the surface of the conductor layer 11. As a result, by making the light at the time of exposure incident to the wiring pattern region, the photosensitive resin near the conductor layer 11 is cured so that the opening inclined part Pa is formed.

As shown in FIG. 4F, a plated metal layer 2P for the wiring conductor, having the wiring inclined part 2a corresponding to the opening inclined part Pa, is filled in the opening pattern P. The plated metal layer 2P is formed by allowing a conductor pattern formed of an electroless copper plating and an electrolytic copper plating to deposit to the surface of the conductor layer 11 by a known semi-additive method, for example. Next, as shown in FIG. 4G, by removing the resist R for plating, a side surface of the plated metal layer 2P including the wiring inclined part 2a is exposed.

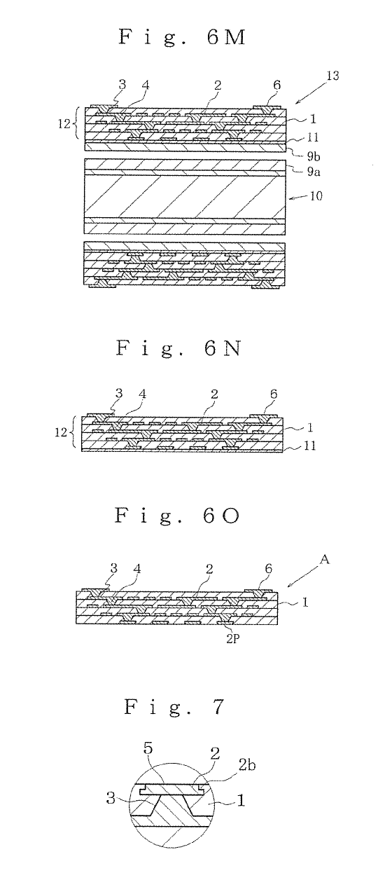

As shown in FIG. 4H, the insulating layer 1 is laminated so as to cover the conductor layer 11 and the plated metal layer 2P. At this time, the insulating layer 1 enters a gap between the conductor layer 11 and the wiring inclined part 2a, and buries the wiring inclined part 2a. Next, as shown in FIG. 4I, the via holes 3 are formed in the insulating layer 1 having the plated metal layer 2P set as a bottom surface. Next, as shown in FIG. 5J, the via conductors 4 are formed in the via holes 3, so that the wiring conductors 2 are formed on the surface of the insulating layer 1. Next, as shown in FIG. 5K, the next insulating layer 1 and the wiring conductors 2 are mutually laminated at a plurality of times in a similar manner, so that the build-up portion 12 for the wiring board is formed.

As described above, each insulating layer 1 is formed of a thermosetting resin such as an epoxy resin or a bismaleimide triazine resin. The insulating layer 1 is formed as follows, for example. First, a film is formed by dispersing an inorganic insulating filler on an uncured substance such as an epoxy resin or bismaleimide triazine resin composition. The insulating layer 1 is formed by thermally compressing the formed film to the surface of the conductor layers 11 on both main surfaces of the supporting substrate 10 and to the surface of the lower insulating layer 1 in a state covered in vacuum. In the insulating layer 1, a plurality of via holes 3 in which a via conductor 4 is filled to enable a conduction between the insulating layers 1 are formed, by laser processing, for example.

As shown in FIG. 5L, the supporting substrate 10, the conductor layer 11, and the build-up portion 12 are cut on the border between the product-forming region X and the margin region Y, so that the supporting substrate 10, the conductor layer 11, and the build-up portion 12 of the product-forming region X are cut out. For this cutting, a dicing device may be used, for example.

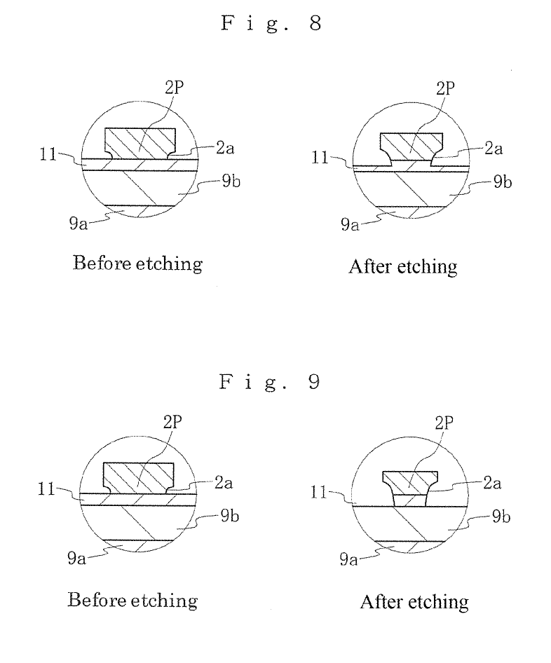

Next, as shown in FIG. 6M, the conductor layer 11 and the build-up portion 12 are separated from the first metal foil 9a. As a result, a laminated body 13 for the wiring board having the second metal foil 9b fixed to a single side of the conductor layer 11 is formed. The second metal foil 9b is separably held by only a small adhesive force on the first metal foil 9a via the adhesion layer. Therefore, the laminated body 13 can be easily separated without damage, by only peeling off the first metal foil 9a from the second metal foil 9b.

Next, as shown in FIG. 6N, the second metal foil 9b is removed by etching. Finally, as shown in FIG. 6O, the conductor layer 11 is entirely removed by an etching liquid. Accordingly, the plated metal layer 2P is exposed. In this way, as shown in FIG. 1, there is formed the wiring board A which has the wiring conductor 2 having the top surface exposed from the insulating layer 1, and including, at a portion buried in the insulating layer 1, the wiring inclined part 2a having a width larger than a width of the top surface.

As described above, according to the method for manufacturing the wiring board in the present disclosure, there is formed the wiring conductor 2 having the top surface exposed from the insulating layer 1 and including, at a portion buried in the insulating layer 1, the wiring inclined part 2a of a width larger than a width of the top surface. In this way, the wiring inclined part 2a of a width larger than a width of the top surface is buried in the insulating layer 1. Therefore, even when miniaturization of the wiring conductor 2 is progressed, the adhesion strength of the wiring conductor 2 does not easily become small, and peeling off of the wiring conductor 2 from the insulating layer 1 can be prevented. As a result, because the electrical signal can be transmitted satisfactorily via the wiring conductor 2, a wiring board enables a stable operation of the semiconductor element.

The wiring board and the method for manufacturing a wiring board in the present disclosure are not limited to the above embodiments, and various modifications are possible without departing from the scope of the present disclosure.

For example, in the wiring board of the one embodiment, the wiring conductor 2 has the wiring inclined part 2a having a width larger than the width of the top surface. However, as shown in FIG. 7, the wiring conductor 2 may have a wiring level difference part 2b having a width larger than the width of the top surface. The wiring board of the one embodiment does not have a solder resist layer deposited to the surface of the outermost insulating layer. However, the solder resist layer may be deposited.

For example, according to the method for manufacturing of the one embodiment, the insulating layer 1 is covered after the resist R for plating is removed, as shown in FIGS. 4A to 4I. However, after the resist R for plating is removed, there may be added a process of etching the conductor layer 11 and the plated metal layer 2P, as shown in FIG. 8 and FIG. 9.

By such an etching process, the surface of the conductor layer 11 and the surface of the plated metal layer 2P are gradually solved. On the other hand, in the wiring inclined part 2a formed in the plated metal layer 2P, the etching liquid remains and the solving speed becomes faster than in other parts. Therefore, as compared with the case of not performing the etching process, the region that the wiring inclined part 2a occupies in the plated metal layer 2P is enlarged. By enlarging in this way the wiring inclined part 2a buried in the insulating layer 1, the adhesion strength of the wiring conductor 2 can be more improved.

What is claimed is:

1. A wiring board comprising an insulating layer and a wiring conductor,
wherein the wiring conductor is buried in the insulating layer in such a manner as to expose a top surface to a surface of the insulating layer, and
wherein the wiring conductor includes, at a portion buried in the insulating layer, a wiring level difference part or a wiring inclined part having a width larger than a width of the top surface.

2. The wiring board according to claim 1, wherein the insulating layer has a multilayer structure, and a wiring conductor buried in the insulating layer in such a manner as to have a top surface exposed to a surface of the insulating layer formed in at least an outermost layer includes, at a portion buried in the insulating layer, a wiring level difference part or a wiring inclined part having a width larger than a width of the top surface.

3. A method for manufacturing a wiring board, comprising:
forming, on an underlying metal layer, a resist layer for plating having an opening pattern including an opening level difference part or an opening inclined part having a width being smaller toward the underlying metal layer;
filling in the opening pattern, with a plated metal layer for a wiring conductor having a wiring level difference part or a wiring inclined part corresponding to the opening level difference part or the opening inclined part, and removing the resist layer for plating;
forming, on the underlying metal layer and on the plated metal layer, an insulating layer burying entirely the plated metal layer, and removing the underlying metal layer by etching; and
forming a wiring conductor so as to have a top surface exposed from the insulating layer and including, at a portion buried in the insulating layer, the wiring level difference part or the wiring inclined part having a width larger than a width of the top surface.

4. The method for manufacturing a wiring board according to claim 3, wherein the underlying metal layer has a flat surface.

5. The method for manufacturing a wiring board according to claim 4, wherein the surface of the underlying metal layer has a surface roughness of 60 nm or lower.

6. The method for manufacturing a wiring board according to claim 3, wherein, after the resist layer for plating is removed, the plated metal layer and the underlying metal layer are further etched.
